(19) United States
(12) Patent Application Publication
(10) Pub. No.: US 2013/0099322 A1
(43) Pub. Date: Apr. 25, 2013

(54) METHOD FOR MANUFACTURING INSULATED-GATE TRANSISTORS

(71) Applicant: STMICROELECTRONICS (CROLLES 2) SAS, Crolles (FR)

(72) Inventors: Emmanuel Perrin, Bernin (FR); Gregory Bidal, Grenoble (FR); Raul Andres Bianchi, Myans (FR)

(73) Assignee: STMICROELECTRONICS (CROLLES 2) SAS, Crolles (FR)

(21) Appl. No.: 13/659,768

(22) Filed: Oct. 24, 2012

(30) Foreign Application Priority Data
Oct. 25, 2011 (FR) 1159659

(51) Int. Cl. H01L 29/78; H01L 21/283

(52) U.S. Cl. 257/368; 438/424; 257/E21.19; 257/E29.255

(57) ABSTRACT

A method for defining an insulating area in a semiconductor substrate, including a step of forming of a bonding layer on the walls and the bottom of a trench defined in the substrate. A step of passivation of the apparent surface of said bonding layer, at least close to the surface of said semiconductor substrate.

### BACKGROUND

1. Technical Field

The present disclosure relates to structures of insulated-gate transistors, for example, MOS transistors. More specifically, the present disclosure relates to a method for manufacturing such a transistor providing a step of adjustment of the transistor threshold voltage.

2. Description of the Related Art

Many MOS transistors manufacturing methods are known. To decrease the dimensions of such transistors, it has been provided to replace the gate insulator of MOS transistors with insulators of high dielectric constant. It has also been provided to adjust the threshold voltage of such transistors, at the end of the manufacturing of their insulated gates, by performing a controlled anneal, which enables the diffusion of atoms modifying the threshold voltage.

FIG. 1 schematically illustrates such a method. In the upper portion of a semiconductor substrate 10 are formed insulating trenches 12 which enable to insulate the different electronic components formed at the surface of substrate 10 from one another. For example, in the case of MOS transistors, trenches 12 delimit the transistor channel regions.

Trenches 12 generally are trenches known as “STI”, for Shallow Trench Isolation, formed of silicon oxide. In practice, the insulating trenches are formed by etching of the upper surface of semiconductor substrate 10 and deposition of an insulating material in the openings defined by etching. A polishing, for example, a chemical-mechanical polishing (CMP), is then performed to only leave the insulating material in the openings.

Insulated gate T of a MOS transistor, formed at the surface of a channel region delimited by trenches 12, comprises a stack of several insulating layers, topped with several conductive layers.

In the shown example, this gate comprises a stack of a first insulating layer 14, of a second heavily-insulating layer 16, of a layer 18 of a material having atoms capable of diffusing towards the insulating material, of a layer of a conductive material 20, and of an upper conductive layer 22 on which is taken the transistor gate contact.

Conventionally, first insulating layer 14, as close as possible to semiconductor substrate 10, is made of silicon oxide or of silicon oxynitride. This layer is necessary to obtain a good interface with the semiconductor material of substrate 10, and generally has a small thickness, on the order of one nanometer. Heavily-insulating layer 16 is made of a material having a high dielectric constant (known as “high-K”). Among such high-K materials, hafnium oxide (HfO₂) or hafnium oxynitride (HfSiON) can for example be mentioned. Other high-K alloys are known.

Layer 18 performs a specific function to adjust the transistor threshold voltage. This layer may for example be made of lanthanum, of aluminum, of magnesium, of dysprosium, or more generally of a material from the category of rare earths, or of an alloy comprising one or several of these materials. When the structure is annealed, lanthanum, aluminum, magnesium, dysprosium atoms of layer 18 diffuse towards the interface between insulating layers 14 and 16 to form a silicate, for example, a lanthanum silicate. This diffusion enables to adjust the transistor threshold voltage, since the material having diffused generates dipoles at the interface between layers 14 and 16, which modify this threshold voltage. The threshold voltage adjustment depends on the thickness of diffusion layer 18, on the duration and on the temperature of the anneal of the structure.

The upper layers 20 and 22 of the insulated gate are layers conventional in the forming of MOS transistors, and will not be detailed any further herein. As an example, layer 20 may be made of a metal such as titanium nitride and layer 22 may be made of polysilicon.

In the case of an association of MOS transistors of different types on a same substrate, different gate structures are generally provided for these transistors, the diffusing layer being placed in the gate stack at different levels for a proper adjustment of the threshold voltage.

### BRIEF SUMMARY

An embodiment provides a method for manufacturing insulated-gate transistors.

More specifically, an embodiment provides a method for manufacturing insulated-gate transistors of adjustable threshold voltage during the manufacturing, while limiting parasitic diffusion phenomena.

Thus, an embodiment provides a method for manufacturing MOS transistors, comprising a step of defining at least one insulating area in a semiconductor substrate, including forming a bonding layer on the walls and the bottom of a trench defined in the substrate, and passivation of the bonding layer, at least close to the surface of the semiconductor substrate, followed by a step of forming an insulated gate on the surface of the substrate and in contact with the insulating area, the gate comprising a stack of at least one first insulating layer of high dielectric constant and of at least one second layer comprising atoms capable of diffusing towards the first layer.

According to an embodiment, the passivation of the bonding layer is obtained by a low-power implantation of carbon or nitrogen atoms in the bonding layer, at least close to the surface of the substrate.

According to an embodiment, the passivation of the bonding layer is obtained by deposition of a passivation layer over the entire bonding layer.

According to an embodiment, the passivation layer is made of aluminum oxide, of lanthanum oxide, or of silicon nitride.

According to an embodiment, the passivation step is followed by a step of filling of the trench with an insulating material.

According to an embodiment, the method comprises a final anneal step so that the atoms of the second layer diffuse towards the first layer.

Another embodiment provides a MOS transistor formed on a device comprising a semiconductor substrate in which are defined insulating trenches, the trenches being separated from the substrate by a bonding layer passivated at least close to the surface of the substrate, further comprising an insulated gate formed at the surface of the substrate in contact with the insulating trenches, the gate comprising at least one first insulating layer of high dielectric constant topped with at least one second layer comprising atoms capable of diffusing towards the first layer.

The foregoing and other features and advantages will be discussed in detail in the following non-limiting description of specific embodiments in connection with the accompanying drawings.

### BRIEF DESCRIPTION OF THE SEVERAL VIEWS OF THE DRAWINGS

FIG. 1, previously described, illustrates a method for forming a known insulated-gate transistor of adjustable threshold voltage;

FIGS. 2, 3A, and 3B illustrate a problem of parasitic diffusion which disturbs the adjustment of the threshold voltage of an insulated-gate transistor formed by known methods; and

FIGS. 4A to 4D and 5A and 5B illustrate results of steps of a method according to two alternative embodiments.

For clarity, the same elements have been designated with the same reference numerals in the different drawings and, further, as usual in the representation of integrated circuits, the various drawings are not to scale.

### DETAILED DESCRIPTION

The method for adjusting the threshold voltage of a MOS transistor by diffusion of diffusing atoms originating from a layer formed above the insulating region of the insulated gate is often of little efficiency in practice. Indeed, the anneal step enabling the diffusion of the atoms of layer 18 towards the interface between layers 14 and 16 also causes many parasitic diffusions in the structure, which disturb the adjustment.

There thus is a need for a method for forming a MOS transistor with an adjustable threshold voltage during the manufacturing method, limiting parasitic diffusions which disturb this adjustment.

The present inventors have noted that, during the diffusion step enabling to adjust the threshold voltage of the transistor comprising gate T, parasitic diffusions occur and cause unwanted variations of the threshold voltage of this transistor. Such parasitic diffusions are caused by parasitic diffusion agents. In particular, the diffusion is accelerated by the presence of silicon and of oxygen. Indeed, since the forming of a silicate is thermodynamically favorable, areas containing silicon and oxygen, in particular, attract diffusing agents.

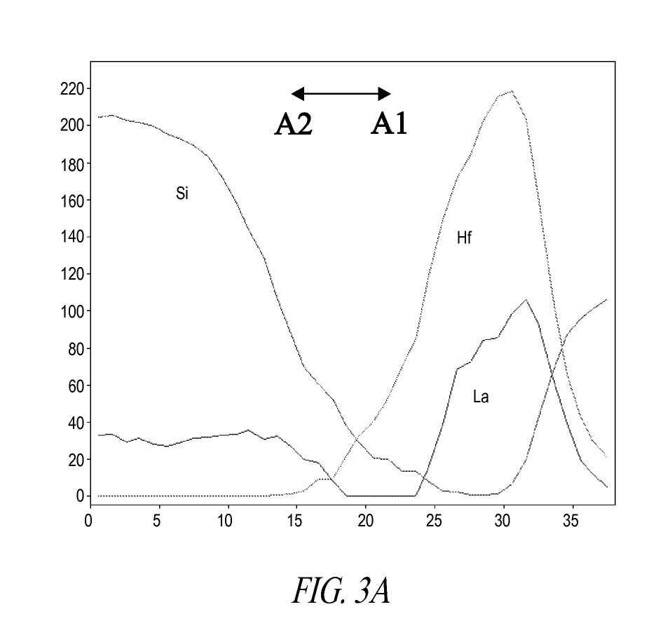

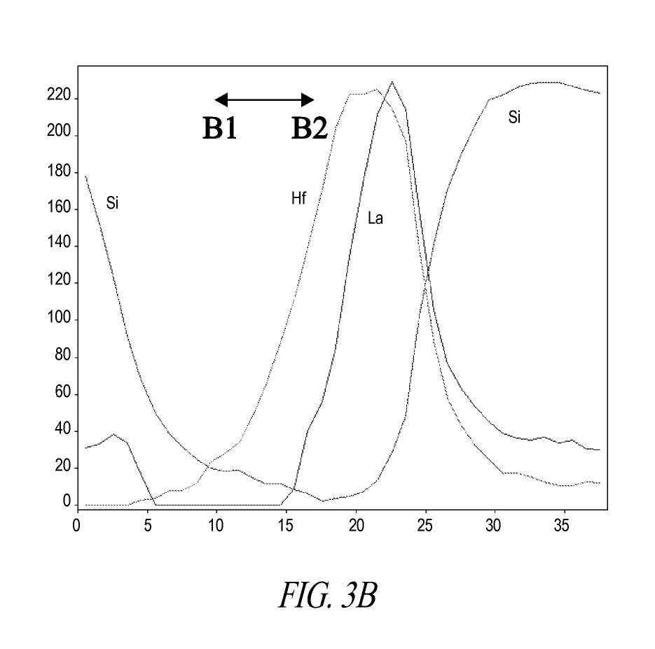

FIGS. 2, 3A, and 3B illustrate a source of such parasitic diffusion agents.

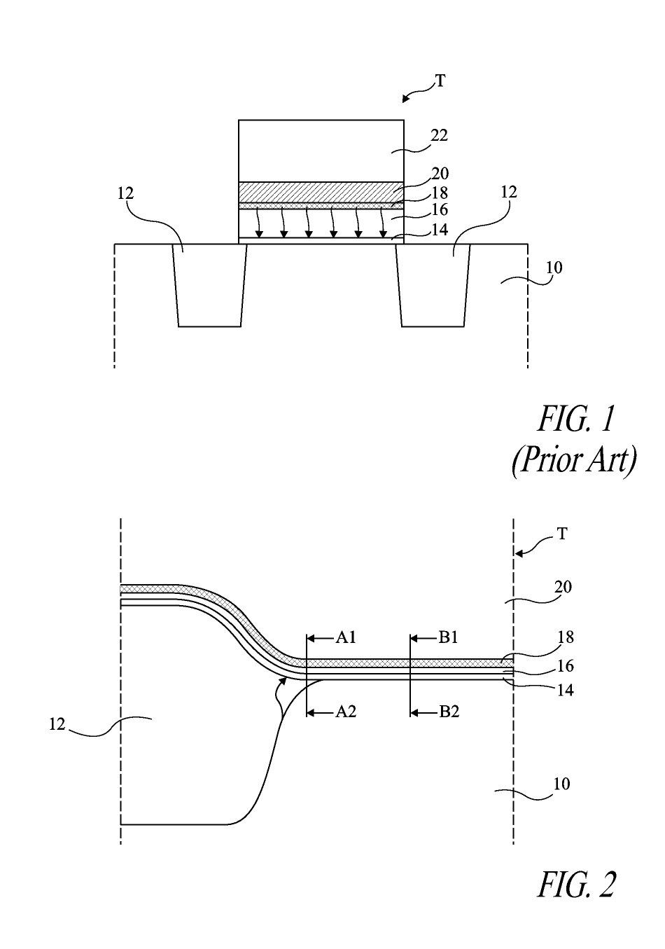

More specifically, FIG. 2 is an enlarged view of the structure of FIG. 1, at the interface between insulated gate T and insulating trenches 12. As illustrated in this drawing, the insulating trenches being in practice bowl-shaped with rounded edges. This shape implies that a region of the gate stack is located in front of thin insulating portions of trenches 12.

FIG. 2 indicates two cross-section axes of the gate stack, at A1-A2 and B1-B2. FIGS. 3A and 3B illustrate the distribution of the different materials of this stack along these cross-sections, in the case where layer 16 is made of hafnium oxide, layer 18 comprises lanthanum atoms, and substrate 10 is made of silicon. The first cross-section A1-A2 is formed vertically in front of the edge of insulating trench 12, and the second cross-section B1-B2 is formed vertically on a portion of the gate stack distant from insulating trench 12.

FIGS. 3A and 3B show the silicon (Si), hafnium (Hf), and lanthanum (La) concentrations along cross-section directions A1-A2 and B1-B2, after the anneal step enabling to diffuse lanthanum towards the interface between layers 14 and 16.

As can be seen in the curves, the amount of lanthanum which has diffused at the interface between layers 14 and 16 is smaller at the level of cross-section A1-A2 than at the level of cross-section B1-B2. During the diffusion, a large number of lanthanum atoms, which should have been fixed at the interface between layers 14 and 16, have leaked. The migration of the diffusing atoms towards trenches 12 modifies the MOS transistor threshold voltage in unwanted fashion.

In particular, the present inventors have noted that the parasitic diffusion species come from the interfaces between the material forming insulating trenches 12 and the semiconductor material of substrate 10. More specifically, a bonding layer having a thickness ranging between 1.5 and 5 nm is generally formed before the deposition of insulating material in trenches 12. Parasitic diffusions are generated by atoms which form at the interface between the bonding layer and the material of insulating trenches 12 and between the bonding layer and semiconductor substrate 10.

Two manufacturing methods enabling to limit such parasitic diffusions, by a passivation at least of the surface of the bonding layer of trenches 12, at least close to the substrate surface.

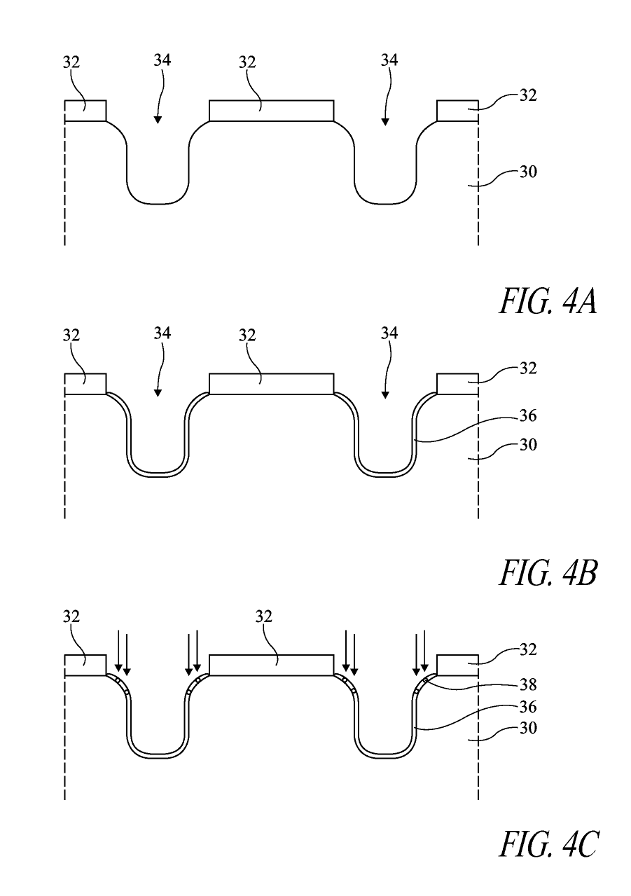

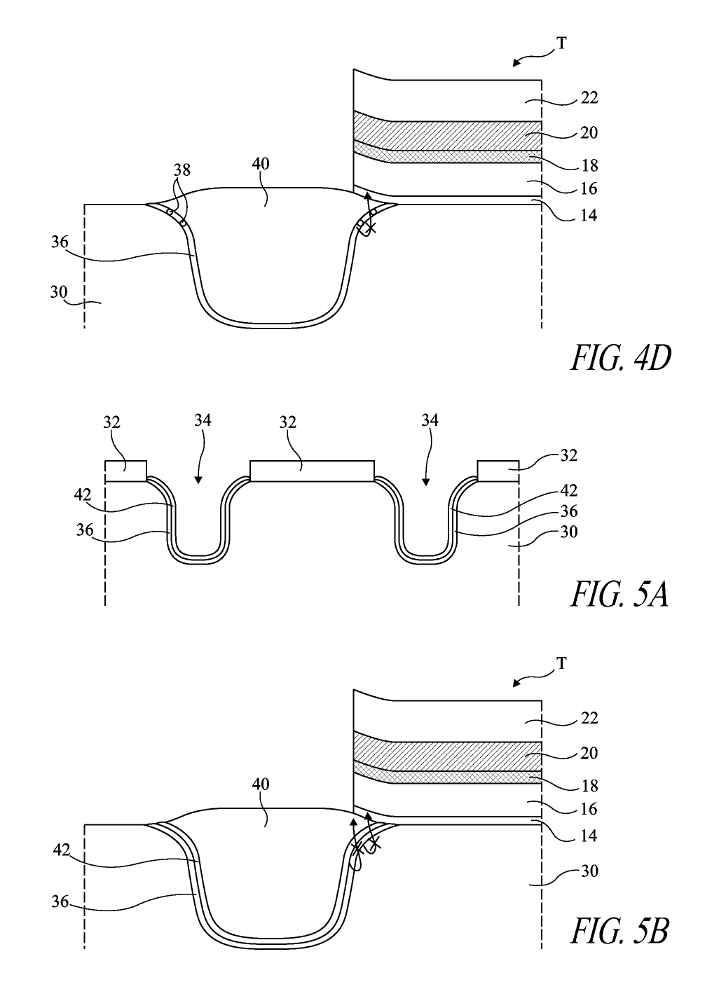

FIGS. 4A to 4D illustrate results of steps of a first method according to an embodiment, and FIGS. 5A and 5B illustrate results of steps of a second method according to an embodiment, enabling such a passivation.

In FIG. 4A, it is started from a structure comprising a semiconductor substrate 30 on which a mask 32 comprising openings is formed. Trenches 34 are defined in substrate 30 via the openings of mask 32. Trenches 34 define the locations of future insulating trenches, for example defining the channel regions of MOS transistors.

At the step illustrated in FIG. 4B, a bonding layer 36 has been deposited on the walls and the bottom of trenches 34. Bonding layer 36 may be made of silicon nitride or of silicon oxide. It may for example be formed by deposition of a conformal layer over the entire structure, the portion of the bonding layer formed on mask 32 being removed at the same time as this mask, or the bonding layer 36 may be formed by a growth on the walls and the bottom of trenches 34.

At the step illustrated in FIG. 4C, an implantation of atoms 38 enabling to passivate at least the upper surface of bonding layer 36 has been formed, especially to avoid the above-described parasitic diffusions. Among atoms adapted to such a passivation by implantation, carbon or nitrogen atoms may be mentioned. Preferably, a low-power implantation will be performed so that carbon or nitrogen atoms only penetrate into the portion of the bonding layer close to the surface of the semiconductor substrate, where parasitic diffusions occur, as close as possible to the insulated gates. This implantation will be provided to dope a thickness ranging from 1.5 to 5 nm of the bonding layer. Indeed, the fact for the entire bonding layer to be passivated matters little in practice, only the upper portion of this layer, at the level of the surface of substrate 30, being responsible for parasitic diffusions. The implantation of atoms 38 is shown in FIG. 4C and in the following drawings by “o”s.

Once the implantation has been performed, an etch step is provided to remove mask 32. A step enabling to fill trenches 34 with insulating material 40 is also carried out. The different layers forming the insulated gates at the surface of the device are finally formed.

FIG. 4D illustrates the result obtained after forming of the insulated gate, in the form of an enlargement at the interface between a trench 40 and a gate T. Gate T is formed of the same layers as the gate illustrated in FIG. 1. It should be noted that gate T may extend above insulating region 40.

As illustrated by an arrow in FIG. 4D, the parasitic diffusion agents which are formed at the interface between bonding layer 36 and substrate 30 and between bonding layer 36 and insulating material 40 are blocked by atoms 38 implanted at the surface of bonding layer 36, and the diffusion of the atoms of layer 18 to the interface between layers 14 and 16 occurs at the center of the gate as well as on the contours thereof.

FIGS. 5A and 5B illustrate a variation of a method according to an embodiment of the present disclosure, enabling to passivate the surface of the bonding layer of the insulating trenches.

At the step illustrated in FIG. 5A, it is started from a device comprising a semiconductor substrate 30 on which is formed a mask 32 comprising openings. Trenches 34 are defined in substrate 30 via mask 32. Trenches 34 define the locations of future insulating trenches delimiting the channel regions of MOS transistors. A bonding layer 36, identical to the bonding layer described in relation with FIG. 4B, has been deposited on the walls and the bottom of trenches 34.

A layer 42 ensuring the passivation of the interface of bonding layer 36 with the insulating material subsequently filling the trenches is then deposited on bonding layer 36. As an example, layer 42 may be made of aluminum oxide (Al₂O₃), or of any other material capable of forming a barrier against the displacement of parasitic diffusion agents formed at the interfaces with the bonding layer. Among such materials, other oxides enabling to block the parasitic diffusion, for example, obtained from the diffusing element(s) of layer 18 may be mentioned, for example, lanthanum oxide, or other materials such as silicon nitride.

Once layer 42 has been formed, an etch step is provided to remove mask 32, and trenches 34 are filled with insulating material 40. The different layers forming an insulated gate at the surface of the device are then formed.

FIG. 5B illustrates the result obtained after forming of the insulated gate, in the form of an enlargement at the interface between a trench 40 and gate T. Gate T is formed of the same layers as the gate illustrated in FIG. 1. As illustrated by arrows in FIG. 5B, the parasitic diffusion agents which are formed on the two surfaces of bonding layer 36 are blocked by barrier layer 42 and have no more influence on the diffusion of the atoms of layer 18 towards the interface between layers 14 and 16.

Various embodiments with different variations have been described hereabove. It should be noted that those skilled in the art may combine various elements of these various embodiments and variations without showing any inventive step. A step of implantation of atoms blocking the passing of parasitic diffusion agents of FIG. 4C may in particular be coupled with a step of forming of a layer blocking the parasitic agents of FIG. 5A, if desired.

Further, gate T described herein may be formed of a stack different from that provided herein, as long as a layer capable of diffusing towards the high-K insulating layer is provided in this stack.

Such alterations, modifications, and improvements are intended to be part of this disclosure, and are within the spirit and the scope of the present disclosure. Accordingly, the foregoing description is by way of example only and is not intended to be limiting. Furthermore, the various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A method for manufacturing MOS transistors, comprising:
forming an insulating area in a semiconductor substrate, the forming including:
forming a trench in a surface of the semiconductor substrate;
forming a bonding layer on walls of the trench; and
passivating at least a portion of the bonding layer; and
forming an insulated gate, on the surface of the substrate and in contact with the insulating area, said gate including a stack of a insulating first layer having a high dielectric constant and a second layer including atoms capable of diffusing towards the first layer.

2. The method of claim 1, wherein the passivating the portion of the bonding layer includes performing a low-power implantation of one of carbon or nitrogen atoms in said bonding layer.

3. The method of claim 1, wherein the passivating the portion of the bonding layer includes depositing a passivation layer over the bonding layer.

4. The method of claim 3, wherein the passivation layer is made of at least one of aluminum oxide, lanthanum oxide, or silicon nitride.

5. The method of claim 1, comprising, following the passivating, filling the trench with an insulating material.

6. The method of claim 1, comprising diffusing atoms of the second layer towards the first layer in an anneal process.

7. A method, comprising:
forming a trench in a substrate of semiconductor material;
forming a bonding layer on walls of the trench;
positioning insulating material in the trench;
forming a transistor gate on a face of the substrate and extending at least as far as an edge of the trench, including:
depositing a first gate layer on the face of the substrate,
depositing a second gate layer on the first gate layer, and
diffusing atoms from the second gate layer to the first gate layer; and
while diffusing the atoms, blocking parasitic diffusion agents that form on surfaces of the bonding layer from affecting the diffusing.

8. The method of claim 7 wherein the blocking the parasitic diffusion agents comprises passivating a portion of the bonding layer by implanting passivation material into a surface of the bonding layer.

9. The method of claim 8 wherein the passivation material comprises atoms of one of carbon and nitrogen.

10. The method of claim 7 wherein the blocking the parasitic diffusion agents comprises forming a passivation layer on the walls of the trench between the bonding layer and the insulating material.

11. The method of claim 7 wherein:
the forming the transistor gate comprises forming a third gate layer on the face of the substrate between the first gate layer and the face of the substrate; and
the diffusing atoms comprises diffusing atoms from the second gate layer toward an interface between the first gate layer and the third gate layer.

12. A device, comprising:
a substrate of semiconductor material;
an insulating trench extending into the substrate from a face of the substrate;
insulating material positioned in the insulating trench;
a bonding layer positioned on walls of the trench and between the walls of the trench and the insulating material, a portion of the bonding layer being passivated;
a MOS device including a channel region positioned in the substrate adjacent to the trench; and
an insulated gate positioned on the face of the substrate, over the channel region, and at least on an edge of the trench.

13. The device of claim 12 wherein the bonding layer includes passivating material implanted into a surface of the bonding layer.

14. The device of claim 12, comprising a passivation layer positioned on the walls of the trench between the bonding layer and the insulating material.

15. The device of claim 12 wherein the insulated gate includes a dielectric layer positioned on the substrate, and a diffusion material layer positioned on the dielectric layer, atoms of the diffusion material layer being positioned on a side of the dielectric layer opposite the diffusion material layer.

16. A device, comprising:
a substrate of semiconductor material;
an insulating trench extending into the substrate from a face of the substrate;
insulating material positioned in the insulating trench;
a bonding layer positioned on walls of the trench between the walls of the trench and the insulating material;
a MOS device including a channel region positioned in the substrate adjacent to the trench;
an insulated gate positioned on the face of the substrate over the channel region and extending at least to an edge of the trench, the insulated gate including a diffusion material layer positioned on the substrate and a dielectric layer positioned on the substrate between the substrate and the diffusion material layer, with atoms of the diffusion material layer positioned on a side of the dielectric layer opposite the diffusion material layer; and
means for blocking parasitic diffusion agents that form on surfaces of the bonding layer from affecting diffusion of the atoms through the dielectric layer.

17. The device of claim 16 wherein the means for blocking comprise a passivating material implanted into a surface of the bonding layer.

18. The device of claim 17 wherein the passivating material comprises atoms of at least one of carbon and nitrogen.

19. The device of claim 16 wherein the means for blocking comprise a passivation layer positioned on the walls of the trench between the bonding layer and the insulating material.

20. The device of claim 19 wherein the passivation layer comprises atoms of at least one of aluminum oxide, lanthanum oxide, or silicon nitride.
